(19) United States
(12) Patent Application Publication
(10) Pub. No.: US 2012/0295013 A1
(43) Pub. Date: Nov. 22, 2012

(54) ELECTROLESS PLATING APPARATUS, METHOD OF ELECTROLESS PLATING, AND MANUFACTURING METHOD OF PRINTED CIRCUIT BOARD

(75) Inventor: Makoto TSUNEKAWA, Osaka (JP)

(73) Assignee: NITTO DENKO CORPORATION, Osaka (JP)

(21) Appl. No.: 13/461,853

(22) Filed: May 2, 2012

(30) Foreign Application Priority Data
May 19, 2011 (JP) 2011-112647

(51) Int. Cl. B05D 5/12; H05K 3/00; B05C 3/09

(52) U.S. Cl. 427/8; 118/712

(57) ABSTRACT

An electroless plating solution is accommodated in a plating tank of an electroless plating apparatus. A reference electrode and a counter electrode are immersed in the electroless plating solution. A conductive member is provided to be electrically in contact with a conductive portion of a long-sized substrate. The conductive member, the reference electrode, and the counter electrode are connected to a potentiostat. A main control device controls the potential of the conductive portion of the long-sized substrate by a potentiostat such that the potential of the conductive portion of the long-sized substrate with respect to a potential of the reference electrode is equal to a potential of the independent portion of the long-sized substrate with respect to the potential of the reference electrode.

### BACKGROUND OF THE INVENTION

(1) Field of the Invention

The present invention relates to an electroless plating apparatus, an electroless plating method, and a manufacturing method of a printed circuit board.

(2) Description of Related Art

In general, electroless plating is the process of depositing metals on the surface of an object to be plated by a reduction reaction without any electric current applied, in which a catalyst is attached on the surface of the object which is then immersed in an electroless plating solution. The electroless plating also allows plating of the surface of an insulting member with a metal film. Thus, the electroless plating has been widely used in the industry.

In recent years, various types of electronic equipment employ high-density and high-fineness printed circuit boards. In manufacturing such printed circuit boards, a metal thin film of nickel, chromium, or the like is formed on the surface of a wiring trace of copper by the electroless plating. In this case, the metal thin film can also be formed on very small conductive portions and insulator portions where establishing conduction is difficult.

In contrast to electroplating, the growth rate of the metal thin film is slow in the electroless plating, but thickness variations within the surface are small. Therefore, the electroless plating is useful for providing a uniform metal thin film that does not require a large thickness.

JP 4-152261 A describes an electroless plating deposition rate measuring apparatus that measures a deposition rate of an electroless plating solution for the optimization of the thickness of the metal thin film formed by the electroless plating. The electroless plating deposition rate measuring apparatus measures a polarization resistance by periodic application of a voltage between an electrode pair in the electroless plating solution, and calculates the deposition rate of the electroless plating solution based on the measured polarization resistance. JP 4-152261 A describes that, by the use of the calculated deposition rate, the thickness of the metal thin film formed by the electroless plating is controlled to be an optimized value.

When the object is immersed in the electroless plating solution in the presence of a reference electrode in the electroless plating solution, a potential difference of about −450 V occurs between the object and the reference electrode. This potential difference comes to a steady state at about −950 V after a transient time of about several tens of seconds has passed. In this state, a chemical reaction of the plating process is started.

However, the transient time is affected by several factors including components of the electroless plating solution, temperature and an index of hydrogen ions of the electroless plating solution. In this context, an electroless plating apparatus described in JP 1-275771 A includes a first electrode which is in contact with the electroless plating solution and a second electrode which is in contact with the object. A voltage of −950 V is applied to the second electrode for two seconds from the stable power supply. A chemical reaction of electroless plating is thus forced to begin. As such, plating time is controlled.

### BRIEF SUMMARY OF THE INVENTION

As described above, the electroless plating deposition rate measuring apparatus of JP 4-152261 A can be used to measure a metal deposition rate of the electroless plating solution. Also, the electroless plating apparatus of JP 1-275771 A can be used to forcedly start the chemical reaction of plating process at a particular time.

However, there is a case where the object has a plurality of portions to be plated, which have different deposition potentials. In this case, if metal thin films are formed on each of the plurality of portions of the object by electroless plating, the resulting films have different thicknesses.

An object of the present invention is to provide an electroless plating apparatus and an electroless plating method capable of forming uniform metal thin films on the surface of a conductive portion and an independent portion which is electrically separated from the conductive portion of an object, and a manufacturing method of a printed circuit board using the same.

(1) According to an aspect of the present invention, an electroless plating apparatus that performs electroless plating on an object having a conductive portion and an independent portion which is electrically separated from the conductive portion includes a plating tank for accommodating an electroless plating solution which contains a metal as a plating material, a reference electrode arranged to be in contact with the electroless plating solution in the plating tank, and a controller that controls a potential of the conductive portion of the object with respect to a potential of the reference electrode such that the potential of the conductive portion of the object with respect to the potential of the reference electrode is equal to a potential of the independent portion of the object with respect to the potential of the reference electrode.

In the electroless plating apparatus, the potential of the conductive portion of the object with respect to the potential of the reference electrode is controlled such that the potential of the conductive portion of the object with respect to the potential of the reference electrode is equal to the potential of the independent portion of the object with respect to the potential of the reference electrode. Accordingly, metal thin films having the same thickness are formed on the surfaces of the conductive portion and the independent portion of the object. As a result, uniform metal thin films can be provided on the surfaces of the conductive portion and the independent portion of the object.

(2) The controller may previously acquire the potential of the independent portion of the object with respect to the potential of the reference electrode, and may control the potential of the conductive portion of the object with respect to the potential of the reference electrode such that the potential of the conductive portion of the object with respect to the potential of the reference electrode is equal to the acquired potential of the independent portion.

In this case, it is not necessary to monitor the potential of the independent portion of the object with respect to the potential of the reference electrode during the electroless plating. Therefore, the configuration of the electroless plating apparatus is not complicated.

(3) The controller may change the potential of the conductive portion of the object with respect to the potential of the reference electrode based on a change of the potential of the independent portion of the object with respect to the potential of the reference electrode.

In this case, even when the potential of the independent portion of the object with respect to the potential of the reference electrode is changed due to a change of state of the electroless plating solution, it is possible to form the metal thin films having the same thickness on the surfaces of the conductive portion and the independent portion of the object.

(4) The controller may previously acquire a relationship between an amount of the object processed in the electroless plating solution and a potential of the independent portion of the object with respect to the potential of the reference electrode as a first relationship, and may control the potential of the conductive portion of the object with respect to the potential of the reference electrode based on the acquired first relationship and an amount of the object processed to date in the electroless plating solution.

As a larger amount of the object is processed in the electroless plating solution, deterioration of the electroless plating solution progresses. To address this, the relationship between the amount of the object processed in the electroless plating solution and the potential of the independent portion of the object with respect to the potential of the reference electrode is previously acquired as the first relationship. Based on the acquired first relationship and the amount of the object processed to date in the electroless plating solution, the potential of the conductive portion of the object with respect to the reference electrode can be controlled such that the potential of the conductive portion of the object with respect to the potential of the reference electrode is equal to the potential of the independent portion of the object with respect to the potential of the reference electrode. Thus, it is possible to form the metal thin films having the same thickness on the surfaces of the conductive portion and the independent portion of the object, even when the deterioration of the electroless plating solution progresses due to the increase of the processed amount of the object.

(5) The electroless plating apparatus may further include a measuring device that measures an oxidation-reduction potential of the electroless plating solution in the plating tank, and the controller may previously acquire a relationship between a potential of the independent portion of the object with respect to the potential of the reference electrode and an oxidation-reduction potential of the electroless plating solution as a second relationship, and may control the potential of the conductive portion of the object with respect to the potential of the reference electrode based on the oxidation-reduction potential measured by the measuring device and the acquired second relationship.

In this case, a change of potential of the independent portion of the object can be detected based on the change of potential of the oxidation-reduction potential during the electroless plating. Therefore, even when the potential of the independent portion of the object with respect to the potential of the reference electrode is changed due to a change of state of the electroless plating solution, the potential of the conductive portion of the object with respect to the potential of the reference electrode can be controlled such that the potential of the conductive portion of the object with respect to the potential of the reference electrode is equal to the detected potential of the independent portion with respect to the potential of the reference electrode. As a result, it is possible to automatically form the metal thin films having the same thickness on the surfaces of the conductive portion and the independent portion of the object, even when the state of the electroless plating solution is changed.

(6) The electroless plating apparatus may further include a transporting device that transports the object in the electroless plating solution of the plating tank, and the controller may previously acquire a relationship between a potential of the conductive portion of the object with respect to the potential of the reference electrode and a metal thin film growth rate on the conductive portion as a third relationship, and may control a transport speed of the object by the transporting device based on the acquired third relationship.

As the potential of the conductive portion of the object with respect to the potential of the reference electrode is changed, the growth rate of the metal thin film on the conductive portion is also changed. To address this, the relationship between the potential of the conductive portion of the object with respect to the reference electrode and the growth rate of the metal thin film on the conductive portion is acquired as the third relationship. Based on the acquired third relationship, the transport speed of the object by the transporting apparatus can be controlled. As a result, it is possible to form the metal thin films having the same thickness uniformly on the surfaces of the conductive portion and the independent portion, even when the potential of the independent portion of the object with respect to the potential of the reference electrode is changed due to the change of state of the electroless plating solution.

(7) The electroless plating apparatus may further include a counter electrode arranged to be in contact with the electroless plating solution in the plating tank, and the controller may control an electric current that flows between the conductive portion of the object and the counter electrode such that the potential of the conductive portion of the object with respect to the potential of the reference electrode is equal to the potential of the independent portion of the object with respect to the potential of the reference electrode.

In this case, by controlling the electric current that flows between the conductive portion of the object and the counter electrode, the potential of the conductive portion of the object with respect to the potential of the reference electrode can be easily controlled such that the potential of the conductive portion of the object with respect to the potential of the reference electrode is equal to the potential of the independent portion of the object with respect to the potential of the reference electrode.

(8) According to another aspect of the present invention, an electroless plating method for performing electroless plating on an object having a conductive portion and an independent portion which is electrically separated from the conductive portion includes the steps of accommodating an electroless plating solution containing a metal used as a plating material, arranging a reference electrode in the plating tank so as to be in contact with the electroless plating solution, immersing the object in the electroless plating solution in the plating tank, and controlling a potential of the conductive portion of the object with respect to a potential of the reference electrode such that the potential of the conductive portion of the object with respect to the potential of the reference electrode is equal to the potential of the independent portion of the object with respect to a potential of the reference electrode.

In the electroless plating method, the potential of the conductive portion of the object with respect to the potential of the reference electrode is controlled such that the potential of the conductive portion of the object with respect to the potential of the reference electrode is equal to the potential of the independent portion of the object with respect to the potential of the reference electrode. Thus, metal thin films having the same thickness are formed on the surfaces of the conductive portion and the independent portion of the object. As a result, uniform metal thin films can be provided on the surfaces of the conductive portion and the independent portion of the object.

(9) The step of controlling may include previously acquiring the potential of the independent portion of the object with respect to the potential of the reference electrode, and controlling the potential of the conductive portion of the object with respect to the potential of the reference electrode such that the potential of the conductive portion of the object with respect to the potential of the reference electrode is equal to the acquired potential of the independent portion.

In this case, it is not necessary to monitor the potential of the independent portion of the object with respect to the potential of the reference electrode during the electroless plating. Therefore, the configuration of the electroless plating apparatus is not complicated.

(10) The step of controlling may include changing the potential of the conductive portion of the object with respect to the potential of the reference electrode based on a change of the potential of the independent portion of the object with respect to the potential of the reference electrode.

In this case, even when the potential of the independent portion of the object with respect to the potential of the reference electrode is changed due to a change of state of the electroless plating solution, it is possible to form the metal thin films having the same thickness on the surfaces of the conductive portion and the independent portion of the object.

(11) The step of controlling may include previously acquiring a relationship between an amount of the object processed in the electroless plating solution and a potential of the independent portion of the object with respect to the potential of the reference electrode as a first relationship, and controlling the potential of the conductive portion of the object with respect to the potential of the reference electrode based on the acquired first relationship and an amount of the object processed to date in the electroless plating solution.

As a larger amount of the object is processed in the electroless plating solution, deterioration of the electroless plating solution proceeds. To address this, the relationship between the amount of the object processed in the electroless plating solution and the potential of the independent portion of the object with respect to the potential of the reference electrode is previously acquired as the first relationship. Based on the acquired first relationship and the amount of the object processed to date in the electroless plating solution, the potential of the conductive portion of the object with respect to the reference electrode can be controlled such that the potential of the conductive portion of the object with respect to the potential of the reference electrode is equal to the potential of the independent portion of the object with respect to the potential of the reference electrode. Thus, it is possible to form the metal thin films having the same thickness on the surfaces of the conductive portion and the independent portion of the object, even when the deterioration of the electroless plating solution proceeds due to the increase of the processed amount of the object.

(12) The step of controlling may include measuring an oxidation-reduction potential of the electroless plating solution in the plating tank, previously acquiring a relationship between a potential of the independent portion of the object with respect to the potential of the reference electrode and an oxidation-reduction potential of the electroless plating solution as a second relationship, and controlling the potential of the conductive portion of the object with respect to the potential of the reference electrode based on the measured oxidation-reduction potential and the acquired second relationship.

In this case, a change of the potential of the independent portion of the object can be detected based on the potential change of the oxidation-reduction potential during the electroless plating. Therefore, even when the potential of the independent portion of the object with respect to the potential of the reference electrode is changed due to a change of state of the electroless plating solution, the potential of the conductive portion of the object with respect to the potential of the reference electrode can be controlled such that the potential of the conductive portion of the object with respect to the potential of the reference electrode is equal to the detected potential of the independent portion with respect to the potential of the reference electrode. As a result, it is possible to automatically form the metal thin films having the same thickness on the surfaces of the conductive portion and the independent portion of the object, even when the state of the electroless plating solution is changed.

(13) The electroless plating method may further include the step of transporting the object in the electroless plating solution in the plating tank, and the controlling step may include previously acquiring a relationship between a potential of the conductive portion of the object with respect to the potential of the reference electrode and a metal thin film growth rate on the conductive portion as a third relationship, and controlling a transport speed of the object based on the acquired third relationship.

As the potential of the conductive portion of the object with respect to the potential of the reference electrode is changed, the growth rate of the metal thin film on the conductive portion is also changed. To address this, the relationship between the potential of the conductive portion of the object with respect to the reference electrode and the growth rate of the metal thin film on the conductive portion is acquired as the third relationship. Based on the acquired third relationship, the transport speed of the object by the transporting apparatus can be controlled. As a result, it is possible to form the metal thin films having the same thickness on the surfaces of the conductive portion and the independent portion, even when the potential of the independent portion of the object with respect to the potential of the reference electrode is changed due to the change of state of the electroless plating solution.

(14) According to a still another aspect of the present invention, a method of manufacturing a printed circuit board includes the steps of forming on an insulating layer a conductive pattern having a conductive portion and an independent portion which is electrically separated from said conductive portion, and forming a metal thin film on a surface of the conductive portion and a surface of the independent portion by the electroless plating method according to the another aspect of the present invention.

In this case, uniform metal thin films can be provided on the surfaces of the conductive portion and the independent portion of the printed circuit board with simple control.

As described above, according to the present invention, uniform metal thin films are provided on the surfaces of the conductive portion and the independent portion of the object.

Other features, elements, characteristics, and advantages of the present invention will become more apparent from the following description of preferred embodiments of the present invention with reference to the attached drawings.

### BRIEF DESCRIPTION OF THE SEVERAL VIEWS OF THE DRAWING

FIG. 1 is a schematic diagram showing an electroless plating apparatus according to an embodiment of the present invention;

FIGS. 2 (a) and (b) are sectional views schematically showing an example of an object to be plated;

FIG. 3 is a graph showing an example of measurement results of a relationship between the potential of the conductive portion and the thickness of the metal thin film;

FIG. 4 is a graph showing an example of a relationship among the potential of the conductive portion, a transport speed of the long-sized substrate, and the thickness of the metal thin film in the electroless plating apparatus of FIG. 1;

FIG. 5 is a schematic diagram showing an electroless plating apparatus according to another embodiment of the present invention;

FIG. 6 is a schematic diagram of an electroless plating system used to perform electroless plating on the long-sized substrate of FIG. 2 (a) in an inventive example;

FIG. 7 is a schematic diagram of an electroless plating system used to perform electroless plating on the long-sized substrate of FIG. 2 (a) in a comparative example 1; and

FIG. 8 is a schematic diagram of an electroless plating system used to perform electroless plating on the long-sized substrate of FIG. 2 (a) in a comparative example 2.

### DESCRIPTION OF THE PREFERRED EMBODIMENTS

Description will be made of an electroless plating apparatus and an electroless plating method according to an embodiment of the present invention while referring to the drawings.

### (1) Configuration of the Electroless Plating Apparatus

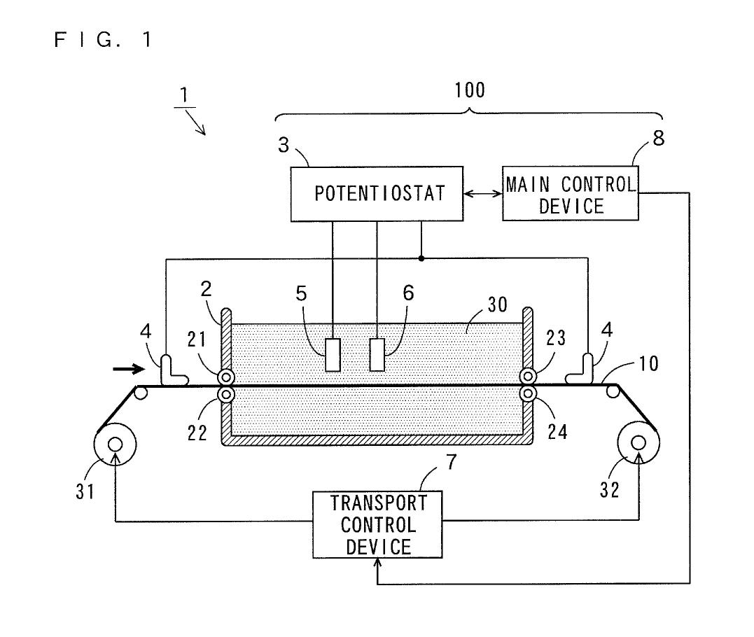

FIG. 1 is a schematic diagram showing a configuration of an electroless plating apparatus according to an embodiment of the present invention. An electroless plating apparatus 1 of FIG. 1 is used to plate a long-sized substrate 10 which is an object to be plated.

The electroless plating apparatus 1 of FIG. 1 includes a plating tank 2. The plating tank 2 contains an electroless plating solution 30. In this embodiment, the electroless plating solution 30 includes nickel (Ni) ions.

Openings are provided, one in each of a pair of opposite side walls of the plating tank 2. A pair of horizontally extending feed rollers 21, 22 are rotatably provided to close one of the openings. Also, a pair of horizontally extending feed rollers 23, 24 are rotatably provided to close the other of the openings.

The long-sized substrate 10 is fed from a feed roll 31. The long-sized substrate 10 passes between the feed rollers 21, 22 into the plating tank 2 and proceeds through the pair of feed rollers 23, 24 to be wound by a winder roll 32. Thus, the long-sized substrate 10 is transported in the direction of an arrow by the rotation of the feed roll 31 and the winder roll 32. A rotational speed of the feed roll 31 and the winder roll 32 is controlled by a transport control device 7, which in turn controls the feeding speed of the long-sized substrate 10.

The long-sized substrate 10 is a semi-finished product, for example, of the manufacturing process of suspension board with a circuit. The semi-finished product includes, in this order, a long-sized metal substrate made of stainless steel, for example, an insulating layer made of polyimide, for example, and a conductive layer (a conductive trace) made of copper, for example, and having a predetermined pattern. The conductive layer is a wiring, a pad electrode, or a ground conductor, for example. The conductive layer has multiple portions which are electrically separated from each other. Among the multiple portions, a portion that can be electrically connected to a conductive member 4, which will be described later, is referred to as a conductive portion, and another portion that is electrically separated from the conductive portion is referred to as an independent portion.

The electroless plating apparatus 1 includes a potentiostat 3, a main control device 8, a pair of conductive members 4, a reference electrode 5 and a counter electrode 6. The potentiostat 3 and the main control device 8 act as a controller 100. One of the conductive members 4 is disposed in the upstream of the plating tank 2 and is electrically in contact with the conductive portion of the long-sized substrate 10, while the other conductive member 4 is disposed in the downstream of the plating tank 2 and is electrically in contact with the conductive portion of the long-sized substrate 10. In this case, the conductive portion of the long-sized substrate 10 acts as a working electrode.

The reference electrode 5 and the counter electrode 6 are immersed in the electroless plating solution 30 contained in the plating tank 2. The reference electrode 5 is a saturated caromel electrode, for example. The counter electrode 6 is an insoluble electrode made of platinum (Pt), for example. The counter electrode 6 acts as an anode (positive electrode) and the conductive portion of the long-sized substrate 10 acts as a cathode.

The conductive members 4, the reference electrode 5 and the counter electrode 6 are connected to the potentiostat 3. The main control device 8 controls the operations of the potentiostat 3 and the transport control device 7. The potentiostat 3 controls an electric current at the reference electrode 5 that flows between the conductive portion (working electrode) of the long-sized substrate 10 and the counter electrode 6 to set the potential of the conductive portion (working electrode) of the long-sized substrate 10 to a value designated by the main control device 8. In this case, the main control device 8 directs the potentiostat 3 to control the potential of the conductive portion (working electrode) of the long-sized substrate 10 such that the potential of the conductive portion with respect to the potential of the reference electrode 5 is equal to the potential of the independent portion of the long-sized substrate 10 in a manner described later.

### (2) Example of Object and Electroless Plating Method

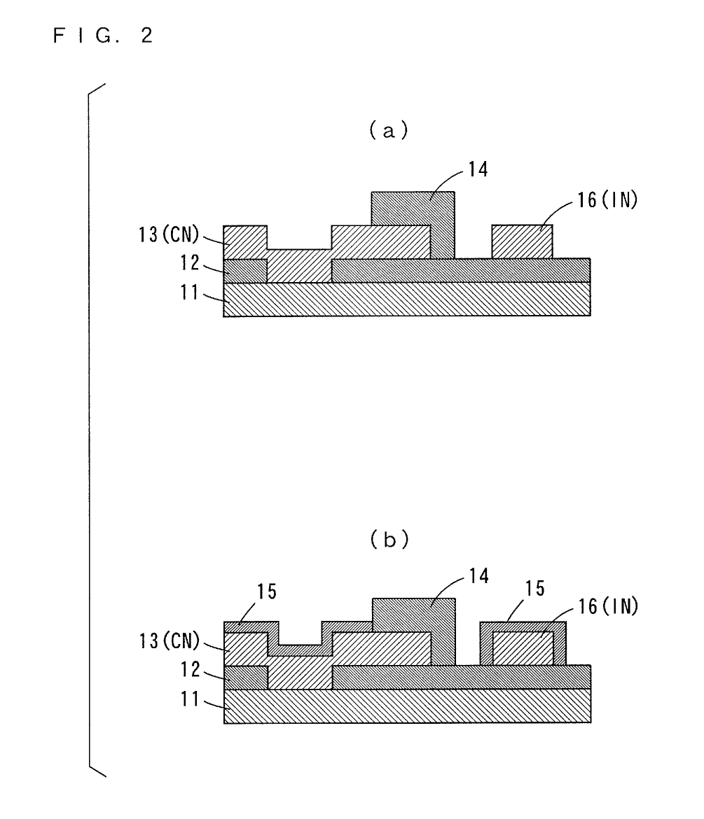

FIG. 2 is a sectional diagram of the object schematically showing an example of the object. FIG. 2(a) shows the object before electroless plating, and FIG. 2(b) shows the object after the electroless plating is done.

The object of FIG. 2 is a suspension board with a circuit made by using the long-sized substrate 10 of FIG. 1. FIG. 2 shows a part of the suspension board with a circuit. As shown in FIG. 2(a), the long-sized substrate 10 includes a metal substrate 11 made of stainless steel, for example. An insulating layer 12 made of polyimide, for example, conductive layers 13, 16 made of copper, and an insulating layer 14 made of polyimide, for example, are sequentially formed on the metal substrate 11. The insulating layer 12 has an opening. Through the opening of the insulating layer 12, the conductive layer 13 is electrically connected to the metal substrate 11. In the example of FIG. 2, the insulating layer 14 is arranged to expose a partial surface of the conductive layer 13 and the entire surface of the conductive layer 16.

In the manufacturing process of the suspension board with a circuit, a metal thin film 15 made of nickel, for example, is formed on the exposed surfaces of the conductive layers 13, 16 by electroless plating, as shown in FIG. 2(b). A thickness of the metal thin film 15 is not less than 0.03 μm nor more than 5 μm, for example.

During the electroless plating of the long-sized substrate 10, the electroless plating solution 30 is accommodated in the plating tank 2 of FIG. 1. In addition, the reference electrode 5 and the counter electrode 6 are disposed in contact with the electroless plating solution 30. Conductive members 4 are disposed electrically in contact with the conductive layer 13 of the long-sized substrate 10. In this example, the conductive layer 13 acts as a conductive portion CN, and the conductive layer 16 acts as an independent portion IN. The conductive members 4 of FIG. 1 may be provided to be in contact with the metal substrate 11.

In this state, the transport control device 7 starts rotation of the feed roll 31 and the winder roll 32, so as to move the long-sized substrate 10 in the electroless plating solution 30 in the plating tank 2. A transport speed of the long-sized substrate 10 by the transport control device 7 is controlled by the main control device 8.

During the transportation of the long-sized substrate 10, the potentiostat 3 controls the electric current that flows between the conductive portion CN of the long-sized substrate 10 and the counter electrode 6 to set the potential of the conductive portion CN of the long-sized substrate 10 with respect to the potential of the reference electrode 5 to a value designated by the main control device 8.

As a result, the metal thin film 15 made of nickel is formed on the exposed surfaces of the conductive portion CN and the independent portion IN of the long-sized substrate 10.

### (3) Controlling Method of the Potential of the Conductive Portion CN

Hereinafter, “the potential of the conductive portion CN with respect to the potential of the reference electrode 5” is abbreviated as “potential of the conductive portion CN.” Similarly, “the potential of the independent portion IN with respect to the reference electrode 5” is abbreviated as “potential of the independent portion IN.”

The potential of the independent portion IN in the electroless plating solution 30 is previously measured. The main control device 8 controls the potential of the conductive portion CN of the long-sized substrate 10 by the potentiostat 3 such that the potential of the conductive portion CN of the long-sized substrate 10 is equal to the potential of the independent portion IN. Consequently, the metal thin films 15 having the same thickness are formed on the surfaces of the conductive portion CN and the independent portion IN of the long-sized substrate 10.

As a larger amount of the long-sized substrate 10 is processed, deterioration of the electroless plating solution 30 progresses. This causes a change of Ni deposition potential on the surface of the independent portion IN of the long-sized substrate 10. Thus, as the processed amount of the long-sized substrate 10 is increased, the potential of the independent portion IN is changed. To address this, a relationship between the processed amount of the long-sized substrate 10 and the potential of the independent portion IN is previously measured. In this embodiment, the processed amount of the long-sized substrate 10 is represented by a length [m] of the long-sized substrate 10 which had been subjected to electroless plating.

For example, the relationship between the processed amount of the long-sized substrate 10 and the potential of the independent portion IN is measured as follows. A palladium (Pd) catalyst is attached to a copper foil to perform Pd catalyst treatment. The reference electrode 5 and the treated copper foil are immersed in the electroless plating solution which has not been used for electroless plating of the long-sized substrate 10. After Ni is deposited on the surface of the copper foil and comes to a stable state, a natural potential (deposition potential of plating) of the copper foil with respect to the potential of the reference electrode 5 is measured. Then, a certain amount of the long-sized substrate 10 is subjected to electroless plating in the electroless plating solution. After this, the reference electrode 5 and the copper foil treated with Pd catalyst are immersed in the electroless plating solution used for electroless plating of the certain amount of the long-sized substrate 10, and the natural potential (deposition potential of plating) of the copper foil with respect to the potential of the reference electrode 5 is measured by the above method after Ni is deposited and stabilized on the surface of the copper foil. Subsequently, every time a certain amount of the long-sized substrate 10 is subjected to electroless plating in the electroless plating solution, the natural potential (deposition potential of plating) of the copper foil with respect to the potential of the reference electrode 5 is repeatedly measured in the above method after Ni is deposited and stabilized on the surface of the copper foil. In this way, the relationship between the processed amount of the long-sized substrate 10 and the deposition potential of plating in the electroless plating solution is measured. The relationship between the processed amount of the long-sized substrate 10 and the deposition potential of plating corresponds to the relationship between the processed amount of the long-sized substrate 10 and the potential of the independent portion IN. It is noted that the relationship between the processed amount of the long-sized substrate 10 and the deposition potential of the independent IN may be measured continuously or for each certain amount of the long-sized substrate 10.

Table 1 below shows an example of measurement results of a relationship (first relationship) between the processed amount of the long-sized substrate 10 and the potential of the independent portion IN.

TABLE 1

| PROCESSED AMOUNT OF | POTENTIAL OF |
|---|---|
| SUBSTRATE (m) | INDEPENDENT PORTION (V) |
| 0 | −0.867 |
| 1000 | −0.836 |
| 2000 | −0.802 |
| 3000 | −0.397 |

In the relationship of Table 1, the potentials of the independent portion IN measured at the processed amount of the long-sized substrate 10 of 0 m, 1000 m, 2000 m and 3000 m are shown. As can be seen from Table 1, the potential of the independent portion IN is increased as the processed amount of the long-sized substrate 10 is increased. The main control device 8 previously stores the relationship of Table 1.

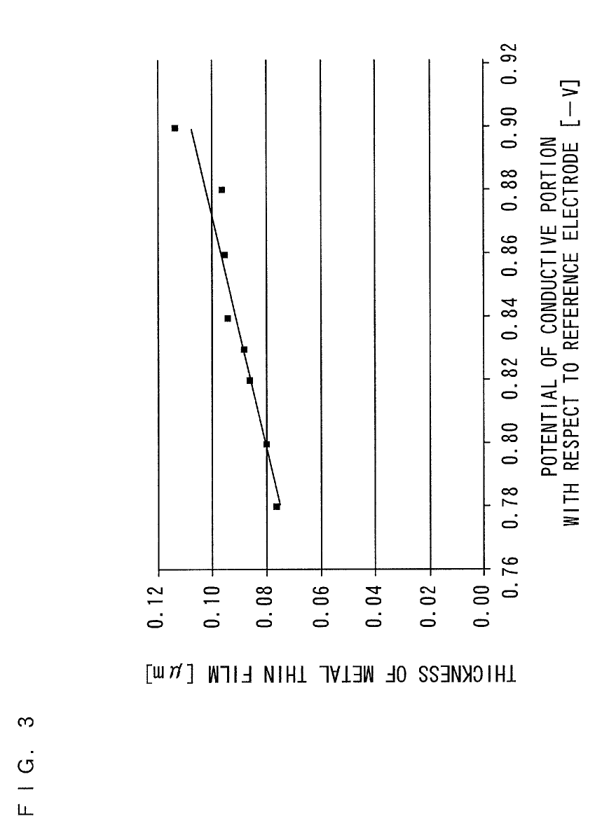

Next, a relationship (third relationship) between the potential of the conductive portion CN and the thickness of the metal thin film 15 formed on the surface of the conductive portion CN is measured previously using the electroless plating apparatus 1 of FIG. 1. FIG. 3 is a graph showing an example of the measurement results of the relationship between the potential of the conductive portion CN and the thickness of the metal thin film 15. The thicknesses of the metal thin film 15 shown in FIG. 3 were obtained after performing the electroless plating for 1 minute.

From the relationship of FIG. 3, a function between the potential of the conductive portion CN and the thickness of the metal thin film 15 is determined. In the example of FIG. 3, a linear function representing the potential of the conductive portion CN and the thickness of the metal thin film 15 is determined.

The relationship of FIG. 3 represents a relationship between the potential of the conductive portion CN and a growth rate of the metal thin film 15. Therefore, from the relationship of FIG. 3, the time of electroless plating during which a metal thin film 15 having a predetermined thickness is formed is determined for each potential of the conductive portion CN.

It is noted that, instead of determining the relationship between the potential of the conductive portion CN and the thickness of the metal thin film 15, a relationship between the potential of the independent portion IN and the thickness of the metal thin film 15 may be determined previously.

Next, a relationship among the potential of the conductive portion CN, a transport speed of the long-sized substrate 10 and the thickness of the metal thin film 15 in the electroless plating apparatus 1 of FIG. 1 is determined by simulation from the relationship of FIG. 3.

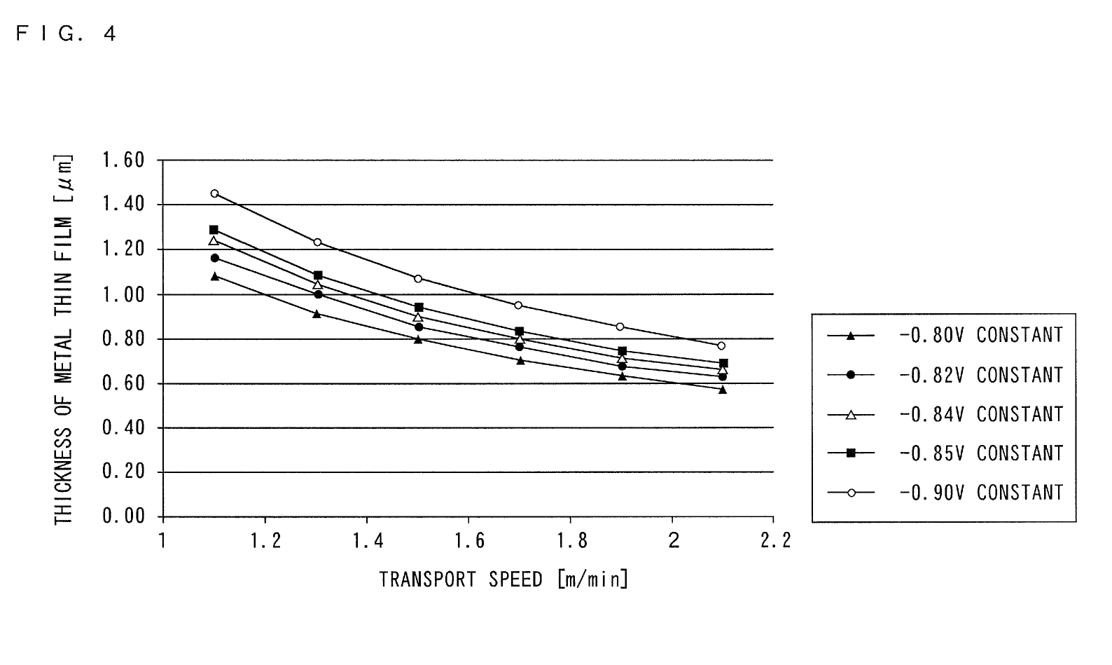

FIG. 4 is an example of the relationship among the potential of the conductive portion CN, the transport speed of the long-sized substrate 10 and the thickness of the metal thin film 15 in the electroless plating apparatus 1 of FIG. 1.

When the transport speed of the long-sized substrate 10 is constant, the lower the potential of the conductive portion CN is, the larger the thickness of the metal thin film 15 is. When the potential of the conductive portion CN is constant, the lower the transport speed of the long-sized substrate 10 is, the smaller the thickness of the metal thin film 15 is.

Thus, it is possible to provide the metal thin film 15 having a constant thickness by reducing the transport speed of the long-sized substrate 10 as the potential of the conductive portion CN is increased.

Table 2 below shows an example of a relationship among the processed amount of the long-sized substrate 10, the potential of the conductive portion CN and the transport speed of the long-sized substrate 10 in order to form the metal thin films 15 having a constant thickness on the surfaces of the conductive portion CN and the independent portion IN of the long-sized substrate 10.

TABLE 2

| PROCESSED | | |
|---|---|---|
| AMOUNT OF | POTENTIAL OF | TRANSPORT |
| SUBSTRATE (m) | CONDUCTIVE PORTION (V) | SPEED (m/min) |
| 0 | −V0 | v0 |
| L1 | −V1 | v1 |
| L2 | −V2 | v2 |
| L3 | −V3 | v3 |

In Table 2, note that 0<L1<L2<L3, −V0<−V1<−V2<−V3 and v0>v1>v2>v3. The main control device 8 previously stores the relationship of Table 2.

As can be seen from Table 2, when the processed amount of the long-sized substrate 10 is equal to or more than 0 [m] and less than L1 [m], the main control device 8 controls the potential of the conductive portion CN to −V0 [V] by the potentiostat 3, so that the potential of the conductive portion CN is equal to the previously measured potential of the independent portion IN. At this time, the main control device 8 controls the transport speed of the long-sized substrate 10 to v0 [m/min] by the transport control device 7.

When the processed amount of the long-sized substrate 10 is not less than L1 [m] and less than L2 [m], the main control device 8 controls the potential of the conductive portion CN to −V1 [V] by the potentiostat 3, so that the potential of the potential of the conductive portion CN is equal to the previously measured potential of the independent portion IN. At this time, the main control device 8 controls the transporting speed of the long-sized substrate 10 to v1 [m/min] by the transport control device 7.

When the processed amount of the long-sized substrate 10 is not less than L2 [m] and less than L3 [m], the main control device 8 controls the potential of the conductive portion CN to −V2 [V] by the potentiostat 3, so that the potential of the potential of the conductive portion CN is equal to the previously measured potential of the independent portion IN. At this time, the main control device 8 controls the transport speed of the long-sized substrate 10 to v2 [m/min] by the transport control device 7.

When the processed amount of the long-sized substrate 10 is not less than L3 [m], the main control device 8 controls the potential of the conductive portion CN to −V3 [V] by the potentiostat 3, so that the potential of the potential of the conductive portion CN is equal to the previously measured potential of the independent portion IN. At this time, the main control device 8 controls the transporting speed of the long-sized substrate 10 to v3 [m/min] by the transport control device 7.

### (4) Effect of the Embodiment

In the electroless plating apparatus 1 according to the embodiment, the potential of the conductive portion CN of the long-sized substrate 10 is controlled such that the potential of the conductive portion CN of the long-sized substrate 10 is equal to the potential of the independent portion IN of the long-sized electrode. As a result, the metal thin films 15 having the same thickness are formed on the surfaces of the conductive portion CN and the independent portion IN of the long-sized substrate 10.

In addition, the potential of the conductive portion CN of the long-sized substrate 10 is controlled based on the previously measured relationship between the processed amount of the long-sized substrate 10 in the electroless plating solution 30 and the potential of the independent portion IN of the long-sized substrate 10 such that the potential of the conductive portion CN of the long-sized substrate 10 is equal to the potential of the independent portion IN of the long-sized substrate 10. As a result, the metal thin films 15 having the same thickness can be formed on the surfaces of the conductive portion CN and the independent portion IN of the long-sized substrate 10, even when the deterioration of the electroless plating solution 30 progresses due to the increase of the processed amount of the long-sized substrate 10.

Further, the transport speed of the long-sized substrate 10 is controlled based on the previously measured relationship between the potential of the conductive portion CN or the independent portion IN of the long-sized substrate 10 and the growth rate of the metal thin film 15. As a result, the metal thin films 15 having the same thickness can be formed on the surfaces of the conductive portion CN and the independent portion IN of the long-sized substrate 10, even when the deterioration of the electroless plating solution 30 progresses due to the increase of the processed amount of the long-sized substrate 10.

Further, the potential of the conductive portion CN of the long-sized substrate 10 with respect to the potential of the reference electrode 5 can be easily controlled by the use of the potentiostat 3.

### (5) Other Embodiments

(5-1)

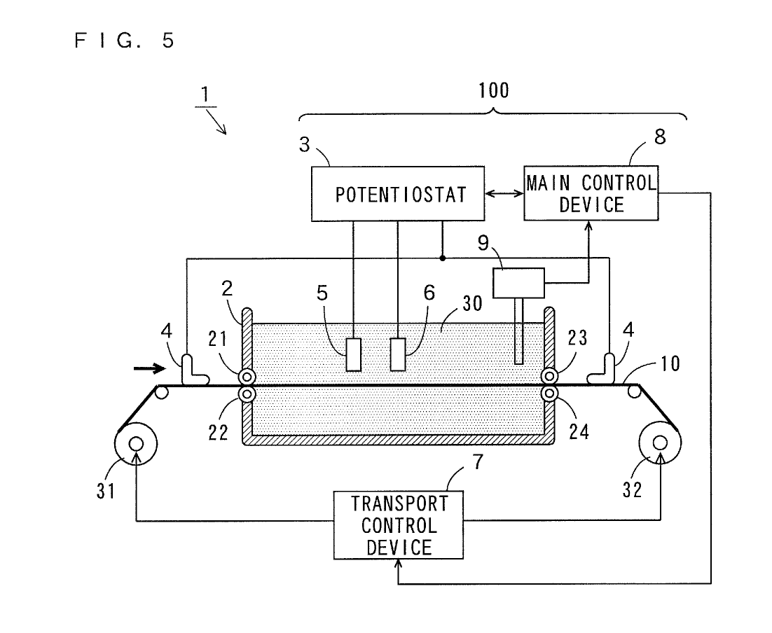

FIG. 5 is a schematic diagram showing the configuration of an electroless plating apparatus 1 according to another embodiment of the present invention.

The electroless plating apparatus 1 of FIG. 5 is different from the electroplating apparatus 1 of FIG. 1 in that an ORP (Oxidation-Reduction Potential) measuring device 9 is added.

A relationship (second relationship) between the potential (deposition potential of plating) of the independent portion IN of the long-sized substrate 10 and an ORP (Oxidation-Reduction Potential) value of the electroless plating solution 30 is previously measured. The main control device 8 stores the previously measured relationship between the potential of the independent portion IN and the ORP (Oxidation-Reduction Potential) value of the electroless plating solution 30.

During the electroless plating of the long-sized substrate 10, the ORP value of the electroless plating solution 30 is measured by the ORP measuring device 9 and provided to the main control device 8. The main control device 8 determines a current potential of the independent portion IN based on the stored relationship between the potential of the independent portion IN and the ORP value of the electroless plating solution 30, and the ORP value from the ORP measuring device 9. As a result, the main control device 8 controls the conductive portion CN of the long-sized substrate 10 by the potentiostat 3 such that the potential of the conductive portion CN of the long-sized substrate 10 is equal to the potential of the independent portion IN. The main control device 8 also controls the transport speed of the long-sized substrate 10 by the transport control device 7 based on the relationship shown in Table 2.

Consequently, the metal thin films 15 having the same thickness can be formed automatically and uniformly on the surfaces of the conductive portion CN and the independent portion IN of the long-sized substrate 10, even when the deterioration of the electroless plating solution 30 progresses due to the increase of the processed amount of the long-sized substrate 10.

(5-2)

In the above embodiment, the electroless plating solution 30 includes nickel ions, but it is not limited thereto. For instance, the electroless plating solution 30 may include other metal ions or an alloy, such as gold (Au), tin (Sn), silver (Ag), copper (Cu), a tin alloy, a copper alloy, or the like.

(5-3)

Also, in the above embodiment, the object is the conductive layer 13 made of copper of the long-sized substrate 10, but the object is not limited thereto. The object may be made of another metal or an alloy such as a copper alloy, nickel (Ni), aluminum (Al), silver (Ag), tin (Sn), or a tin alloy.

(5-4)

Also, in the above embodiment, the object is the long-sized substrate 10 that is a semi-finished product of the suspension board with a circuit, but the object is not limited thereto. The object may be another printed circuit board such as a flexible printed circuit board or a rigid printed circuit board, or a semi-finished product thereof. Further, the object is not limited to the printed circuit board and electroless plating can be performed on various objects using the electroless plating apparatus 1.

(5-5)

In the above embodiment, by the electroless plating of the roll-to-roll system, the conductive layer 13 is subjected to electroless plating while the long-sized substrate 10 is moved, but the present invention is also applicable to an electroless plating apparatus of the batch system. In the electroless plating apparatus of the batch system, the object is immersed for a fixed period of time in the electroless plating solution in the plating tank without being moved. In this case, by controlling the potential of the conductive portion of the object to be equal to the potential of the independent portion of the object, and by controlling the time during which the object is immersed in the electroless plating solution to be fixed, metal thin films having the same thickness can be formed uniformly on the surfaces of the conductive portion and the independent portion of the object.

(5-6)

Further, the above embodiment employs the potentiostat 3 as an example of the controller.

Alternatively, other control circuits may be used as a controller instead of the potentiostat 3.

### (6) Examples

In an inventive example and comparative examples 1 and 2, a metal thin film made of nickel was formed by electroless plating on the surface of the long-sized substrate 10 having the configuration of FIG. 2 (a).

A width of the long-sized substrate 10 is 30 cm. As described below, metal thin films made of nickel were formed on the surfaces of the conductive portion CN and the independent portion IN of the long-sized substrate 10.

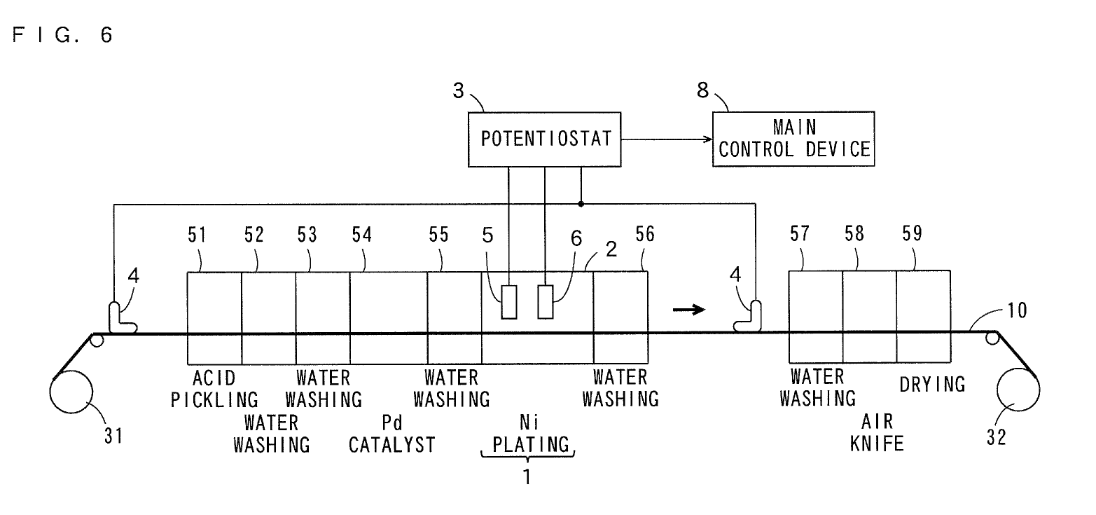

FIG. 6 is a schematic diagram of an electroless plating system used to perform electroless plating on the long-sized substrate 10 of FIG. 2 (a) in the inventive example.

In the electroless plating system of FIG. 6, an acid pickling treatment tank 51, water washing treatment tanks 52, 53, a Pd (palladium) catalyst treatment tank 54 and a water washing treatment tank 55 are arranged sequentially at the upstream side of the electroless plating apparatus 1. At the downstream side of the electroless plating apparatus 1, water washing treatment tanks 56, 57, an air knife treatment tank 58 and a drying treatment tank 59 are arranged sequentially. The configuration of the electroless plating apparatus 1 is similar to that of the electroless plating apparatus 1 shown in FIG. 1.

The long-sized substrate 10 fed from the feed roller 31 passes the treatment tanks 51 to 55, the electroless plating apparatus 1 and the treatment tanks 57 to 59, and is wound by a winder roll 32.

The long-sized substrate 10 is subjected to acid pickling and water washing, successively, in the acid pickling treatment tank 51 and the water washing tanks 52, 53, respectively. Then, a palladium (Pd) catalyst is attached to the surface of the long-sized substrate 10 in the Pd catalyst treatment tank 54. Using the method of the embodiment described above, metal thin films made of nickel (Ni thin films) are formed on the surfaces of the conductive portion CN and the independent portion IN of the long-sized substrate 10 in the electroless plating apparatus 1. After that, the long-sized substrate 10 is subjected to water washing in the water washing treatment tanks 56, 57, followed by blowing off of the water attached to the surface of the long sized substrate 10 in the air knife treatment tank 58, and then the long-sized substrate 10 is dried in the drying treatment tank 59.

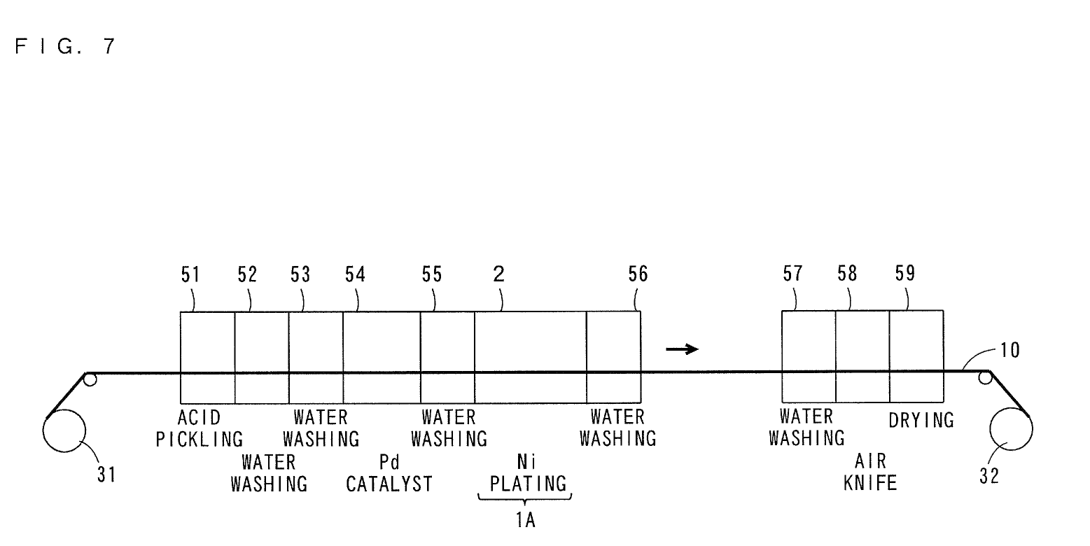

FIG. 7 is a schematic diagram of an electroless plating system used to perform electroless plating of the long-sized substrate 10 of FIG. 2(a) in the comparative example 1.

In the electroless plating system of FIG. 7, an electroless plating apparatus 1A is provided instead of the electroless plating apparatus 1 of FIG. 6. The electroless plating apparatus 1A includes a plating tank 2 that contains the electroless plating solution. The electroless plating apparatus 1A does not include the potentiostat 3, the main control device 8, the conductive members 4, the reference electrode 5 and the counter electrode 6 shown in FIG. 6.

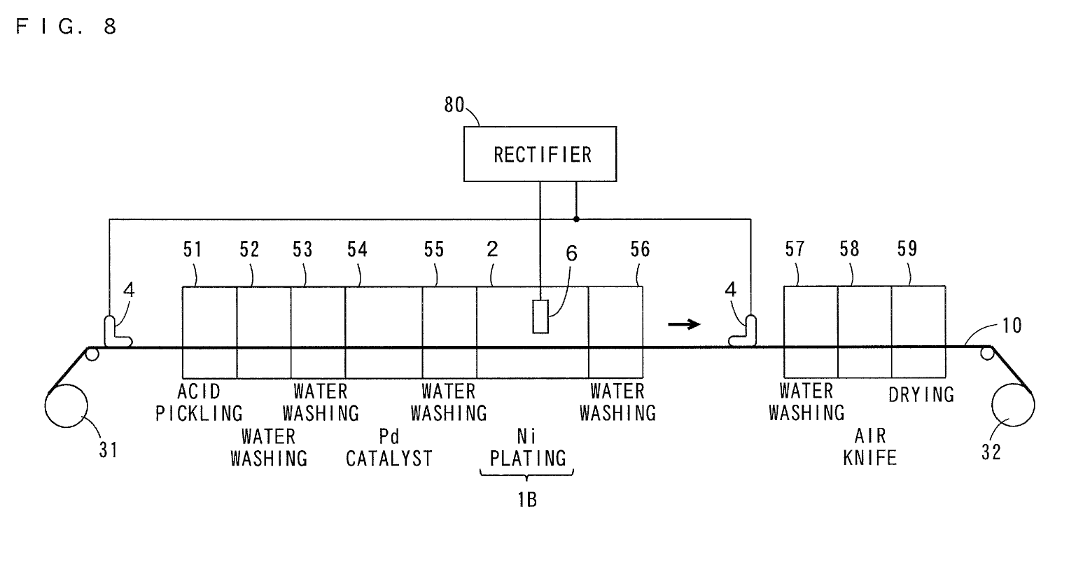

FIG. 8 is a schematic diagram of an electroless plating system used to perform electroless plating of the long-sized substrate 10 of FIG. 2(a) in the comparative example 2. In the electroless plating system of FIG. 8, an electroless plating apparatus 1B is provided instead of the electroless plating apparatus 1 of FIG. 6. In the electroless plating apparatus 1B, a rectifier 80 is provided instead of the potentiostat 3 and the main control device 8 of FIG. 6. The rectifier 80 is connected to the conductive members 4 and the counter electrode 6. The reference electrode 5 of FIG. 6 is not provided.

In the inventive example and the comparative examples 1 and 2, a catalyst treatment was performed for 1 minute at 30° C. in the Pd catalyst treatment tank 54, using ICP Accela from Okuno Chemical Industries, Co., Ltd. as a catalyst. Also, electroless plating was performed at 82° C. in the electroless plating apparatuses 1, 1A and 1B, using ICP Nicoron FPF from Okuno Chemical Industries, Co., Ltd. as an electroless plating solution containing Ni.

In the inventive example, the main control device 8 controlled the potential of the conductive portion CN by the potentiostat 3 based on the relationship between the processed amount of the long-sized substrate 10 and the potential (deposition potential of plating) of the independent portion IN as shown in Table 1 such that the potential of the conductive portion CN is equal to the potential of the independent portion IN. Specifically, when the processed amount of the long-sized substrate 10 was equal to or more than 0 m and less than 1000 m, the potential of the conductive portion CN was controlled to be −0.867 V. When the processed amount of the long-sized substrate 10 was not less than 1000 m and less than 2000 m, the potential of the conductive portion CN was controlled to be −0.836 V. When the processed amount of the long-sized substrate 10 was not less than 2000 m and less than 3000 m, the potential of the conductive portion CN was controlled to be −0.802 V. When the processed amount of the long-sized substrate 10 was not less than 3000 m, the potential of the conductive portion CN was controlled to be −0.397 V.

In addition, the main control device 8 controlled the transport speed of the long-sized substrate 10 by the transport control device 7 based on the relationship among the processed amount of the long-sized substrate 10, the potential of the conductive portion CN, and the transport speed of the long-sized substrate 10 shown in Table 2. When the processed amount of the long-sized substrate 10 was equal to or more than 0 m and less than 1000 m, the transport speed of the long-sized substrate 10 was controlled to be v0 [m/min]. When the processed amount of the long-sized substrate 10 was not less than 1000 m and less than 2000 m, the transport speed of the long-sized substrate 10 was controlled to be v1 [m/min]. When the processed amount of the long-sized substrate 10 was not less than 2000 m and less than 3000 m, the transport speed of the long-sized substrate 10 was controlled to be v2 [m/min]. When the processed amount of the long-sized substrate 10 was not less than 3000 m, the transport speed of the long-sized substrate 10 was controlled to be v3 [m/min].

In the comparative example 1, the potential of the conductive portion CN of the long-sized substrate 10 was not controlled. Also, in the comparative example 1, the transport speed of the long-sized substrate 10 was controlled in the same way as in the inventive example.

In the comparative example 2, by the rectifier 80 of FIG. 8, an electric current of 70 mA was continuously flown between the counter electrode 6 and the conductive portion CN of the long-sized substrate 10. Also, in the comparative example 2, the transport speed of the long-sized substrate 10 was constant.

Table 3 below shows average thicknesses of the Ni thin film formed on the surfaces of the conductive portion CN and the independent portion IN of the long-length substrate 10 in the inventive example and the comparative examples 1 and 2.

TABLE 3

| | THICKNESS OF Ni THIN FILM (μm) | | | | | |
|---|---|---|---|---|---|---|
| | | | AFTER 2000 M | | AFTER 3000 M | |
| | NEW SOLUTION | | WAS PROCESSED | | WAS PROCESSED | |
| | CONDUCTIVE | INDEPENDENT | CONDUCTIVE | INDEPENDENT | CONDUCTIVE | INDEPENDENT |
| | PORTION | PORTION | PORTION | PORTION | PORTION | PORTION |
| INVENTIVE | 0.90 | 0.92 | 0.93 | 0.91 | NO | NO |
| EXAMPLE | | | | | DEPOSITION | DEPOSITION |
| COMPARATIVE | 0.58 | 0.92 | NO | NO | NO | NO |
| EXAMPLE 1 | | | DEPOSITION | DEPOSITION | DEPOSITION | DEPOSITION |
| COMPARATIVE | 0.93 | 0.78 | 0.95 | 0.53 | 0.90 | NO |
| EXAMPLE 2 | | | | | | DEPOSITION |

Average thicknesses of the Ni thin film formed on the surfaces of the conductive portion CN and the independent portion IN of the long-sized substrate 10 were measured at timings when the electroless plating solution was new (new solution), and when the electroless plating was done for 2000 m and 3000 m, respectively, of the long-sized substrate 10. The average thicknesses of the Ni thin film are average values of thicknesses of the Ni thin film at several locations in the width direction of the long-sized substrate 10.

As shown in Table 3, in the inventive example, the average thicknesses of the Ni thin films on the surfaces of the conductive portion CN and the independent portion IN for the new solution were 0.90 μm and 0.92 μm, and the variation was as small as 0.02 μm. The average thicknesses of the Ni thin films on the surfaces of the conductive portion CN and the independent portion IN when the 2000 m of the long-sized substrate 10 had been subjected to electroless plating were 0.93 μm and 0.91 μm, and the variation was also as small as 0.02 μm. The average thicknesses of the Ni thin film on the surface of the conductive portion CN when the solution was new and when 2000 m of the long-sized substrate 10 had been subjected to electroless plating were 0.90 μm and 0.93 μm, respectively, and the variation was as small as 0.03 μm. The average thicknesses of the Ni thin film on the surface of the independent portion IN when the solution was new and when 2000 m of the long-sized substrate 10 had been subjected to electroless plating were 0.92 μm and 0.91 μm, respectively, and the variation was as small as 0.01 μm. When the electroless plating had been done for 3000 m of the long-sized substrate 10, Ni was not deposited on the surfaces of the conductive portion CN and the independent portion IN.

In the comparative example 1, the average thicknesses of the Ni thin film of the new solution on the surfaces of the conductive portion CN and the independent portion IN were 0.58 μm and 0.92 μm, and the variation was as large as 0.34 μm. When the electroless plating had been done for 2000 m of the long-sized substrate 10, Ni was not deposited on the surfaces of the conductive portion CN and the independent portion IN.

In the comparative example 2, the average thicknesses of the Ni thin film of the new solution on the surfaces of the conductive portion CN and the independent portion IN were 0.93 μm and 0.78 μm, and the variation was as large as 0.15 μm. The average thicknesses of the Ni thin film on the surfaces of the conductive portion CN and the independent portion IN when 2000 m of the long-sized substrate 10 had been subjected to electroless plating were 0.95 μm and 0.53 μm, and the variation was as large as 0.42 μm. When the electroless plating had been done for 3000 m of the long-sized substrate 10, the average thickness of the Ni thin film on the surface of the conductive portion CN was 0.90 μm and Ni was not deposited on the surface of the independent portion IN. Further, the average thicknesses of the Ni thin film on the conductive portion CN when the solution was new and when 2000 m and 3000 m of the long-sized substrate 10 had been subjected to electroless plating were 0.93 μm, 0.95 μm and 0.90 μm, respectively, and the variation was as relatively small as 0.05 μm. However, the average thicknesses of the Ni thin film on the surface of the independent portion IN when the electroless plating had been done when the solution was new and when the electroless plating had been done for 2000 m of the long-sized substrate 10 were 0.78 μm and 0.53 μm, and the variation was as large as 0.25 μm.

As such, in the inventive example, the variation of the average thicknesses of the Ni thin films on the surfaces of the conductive portion CN and the independent portion IN was small in comparison with the comparative examples 1 and 2, and the Ni thin films on the surfaces of the conductive portion CN and the independent portion IN had a uniform thickness even when the deterioration of the electroless plating solution progressed. Thus, it was found that the Ni thin films having the same thickness could be formed on the surfaces of the conductive portion CN and the independent portion IN of the long-sized substrate 10, and the uniform Ni thin film could be provided on the surfaces of the conductive portion CN and the independent portion IN even when the deterioration of the electroless plating solution 30 progressed, by controlling the potential of the conductive portion CN of the long-sized substrate 10 to be equal to the potential of the independent portion IN, and by controlling the transport speed of the long-sized substrate 10 based on the potential of the conductive portion CN.

While preferred embodiments of the present invention have been described above, it is to be understood that variations and modifications will be apparent to those skilled in the art without departing the scope and spirit of the present invention. The scope of the present invention, therefore, is to be determined solely by the following claims.

I/We claim:

1. An electroless plating apparatus that performs electroless plating on an object having a conductive portion and an independent portion which is electrically separated from said conductive portion, comprising:
a plating tank for accommodating an electroless plating solution which contains a metal as a plating material;
a reference electrode arranged to be in contact with said electroless plating solution in said plating tank; and
a controller that controls a potential of said conductive portion of said object with respect to a potential of said reference electrode such that the potential of said conductive portion of said object with respect to the potential of said reference electrode is equal to a potential of said independent portion of said object with respect to the potential of said reference electrode.

2. The electroless plating apparatus according to claim 1, wherein
said controller previously acquires the potential of said independent portion of said object with respect to the potential of said reference electrode, and controls the potential of said conductive portion of said object with respect to the potential of said reference electrode such that the potential of said conductive portion of said object with respect to the potential of said reference electrode is equal to said acquired potential of said independent portion.

3. The electroless plating apparatus according to claim 1, wherein
said controller changes the potential of said conductive portion of said object with respect to the potential of said reference electrode based on a change of the potential of said independent portion of said object with respect to the potential of said reference electrode.

4. The electroless plating apparatus according to claim 1, wherein
said controller previously acquires a relationship between an amount of said object processed in said electroless plating solution and a potential of said independent portion of said object with respect to the potential of said reference electrode as a first relationship, and controls the potential of said conductive portion of said object with respect to the potential of said reference electrode based on said acquired first relationship and an amount of said object processed to date in the electroless plating solution.

5. The electroless plating apparatus according to claim 1, further comprising a measuring device that measures an oxidation-reduction potential of the electroless plating solution in said plating tank, wherein
said controller previously acquires a relationship between a potential of said independent portion of said object with respect to the potential of said reference electrode and an oxidation-reduction potential of the electroless plating solution as a second relationship, and controls the potential of said conductive portion of said object with respect to the potential of said reference electrode based on said oxidation-reduction potential measured by said measuring device and said acquired second relationship.

6. The electroless plating apparatus according to claim 1, further comprising a transporting device that transports said object in the electroless plating solution of said plating tank, wherein
said controller previously acquires a relationship between a potential of said conductive portion of said object with respect to the potential of said reference electrode and a metal thin film growth rate on said conductive portion as a third relationship, and controls a transport speed of said object by said transporting device based on said acquired third relationship.

7. The electroless plating apparatus according to claim 1, further comprising a counter electrode arranged to be in contact with the electroless plating solution in said plating tank, wherein
said controller controls an electric current that flows between said conductive portion of said object and said counter electrode such that the potential of said conductive portion of said object with reference to the potential of said reference electrode is equal to the potential of said independent portion of said object with respect to the potential of said reference electrode.

8. An electroless plating method for performing electroless plating on an object having a conductive portion and an independent portion which is electrically separated from said conductive portion, comprising the steps of:
accommodating an electroless plating solution containing a metal used as a plating material;
arranging a reference electrode in said plating tank so as to be in contact with said electroless plating solution;
immersing said object in the electroless plating solution in said plating tank; and
controlling a potential of said conductive portion of said object with respect to a potential of said reference electrode such that the potential of said conductive portion of said object with respect to the potential of said reference electrode is equal to the potential of said independent portion of said object with respect to the potential of said reference electrode.

9. The electroless plating method according to claim 8, wherein
said step of controlling includes
previously acquiring the potential of said independent portion of said object with respect to the potential of said reference electrode, and
controlling the potential of said conductive portion of said object with respect to the potential of said reference electrode such that the potential of said conductive portion of said object with respect to the potential of said reference electrode is equal to said acquired potential of said independent portion.

10. The electroless plating method according to claim 8, wherein
said step of controlling includes changing the potential of said conductive portion of said object with respect to the potential of said reference electrode based on a change of the potential of said independent portion of said object with respect to the potential of said reference electrode.

11. The electroless plating method according to claim 8, wherein said step of controlling includes
previously acquiring a relationship between an amount of said object processed in the electroless plating solution and a potential of said independent portion of said object with respect to the potential of said reference electrode as a first relationship, and
controlling the potential of said conductive portion of said object with respect to the potential of said reference electrode based on said acquired first relationship and an amount of said object processed to date in the electroless plating solution.

12. The electroless plating method according to claim 8, wherein said step of controlling includes
measuring an oxidation-reduction potential of the electroless plating solution in said plating tank,
previously acquiring a relationship between a potential of said independent portion of said object with respect to the potential of said reference electrode and an oxidation-reduction potential of the electroless plating solution as a second relationship, and
controlling the potential of said conductive portion of said object with respect to the potential of said reference electrode based on said measured oxidation-reduction potential and said acquired second relationship.

13. The electroless plating method according to claim 8, further comprising the step of transporting said object in the electroless plating solution in said plating tank, wherein
said step of controlling includes
previously acquiring a relationship between a potential of said conductive portion of said object with respect to the potential of said reference electrode and a metal thin film growth rate on said conductive portion as a third relationship, and
controlling a transport speed of said object based on said acquired third relationship.

14. A method of manufacturing a printed circuit board comprising the steps of:
forming on an insulating layer a conductive pattern having a conductive portion and an independent portion which is electrically separated from said conductive portion; and
forming a metal thin film on a surface of said conductive portion and a surface of said independent portion by the electroless plating method according to claim 7.
